(19) United States
(12) Patent Application Publication
(10) Pub. No.: US 2017/0140951 A1
(43) Pub. Date: May 18, 2017

(54) THREE-DIMENSIONAL WAFER SURFACE WASHING METHOD AND DEVICE

(71) Applicant: IMT CO., LTD., Hwaseong-si (KR)

(72) Inventors: Jong Myoung LEE, Anyang-city (KR); Kyu-pil LEE, Hwaseong-si (KR)

(21) Appl. No.: 15/322,374

(22) PCT Filed: Aug. 25, 2014
(86) PCT No.: PCT/KR2014/007857

§ 371 Date: Dec. 27, 2016

(30) Foreign Application Priority Data
Jul. 7, 2014 (KR) 10-2014-0084237

(51) Int. Cl. H01L 21/67; B08B 5/02; B08B 7/00; H01L 21/683; H01L 21/02

(52) U.S. Cl. CPC H01L 21/67051; H01L 21/6831; H01L 21/02052; H01L 21/02068; H01L 21/6838; B08B 7/00; B08B 5/023

(57) ABSTRACT

Disclosed is an apparatus for removing residues present on the surface of a three-dimensional wafer formed with three-dimensional surface structures to clean the surface of the three-dimensional wafer. The apparatus includes a wafer support for supporting a three-dimensional wafer and a CO₂ dry ice spray unit for producing solid CO₂ dry ice through adiabatic expansion of liquid CO₂ at or near a cleaning nozzle and spraying the solid CO₂ dry ice on the surface of the three-dimensional wafer through the cleaning nozzle. The CO₂ dry ice spray unit includes a liquid CO₂ feeder for supplying, the liquid CO₂ to the cleaning nozzle and an accelerated clean air feeder for supplying clean air to the cleaning nozzle.

### TECHNICAL FIELD

The present invention Maws to techniques for cleaning the such of a three-dimensional wafer. More specifically, the present invention relates to a cleaning method and apparatus for effectively removing residues present on the surface of a three-dimensional wafer in a semiconductor manufacturing process for the fabrication of a multifunctional stack composite device using the three-dimensional wafer.

### BACKGROUND ART

In recent years, numerous efforts have been made to achieve various functions in one device by stacking multifunctional elements at a wafer level. In these efforts, through-silicon via (TSV) techniques are typically used. The use of TSV techniques allows terminal connection between wafers. Terminal connection between wafers or terminal connection between waters and PCBs is accomplished through direct bonding of terminals. The terminals are in the form of micropads or microbumps on the wafers.

Such wafers are referred to as three-dimensional wafers, (a), (b) and (c) of FIG. 1 illustrate representative three-dimensional wafer shapes.

As illustrated in each of (a) and (b) of FIG. 1, contact micropads p or contact microbumps b may be formed as contact terminals on a wafer w. The wafer is connected to an adjacent wafer through the contact pads p or the contact bumps b. The wafer connection through the contact pads p or contact bumps b can reduce the length of paths and enables very fast signal transmission, compared to conventional approaches to connect elements by wire bonding and molding. The reduced path length can lead to low power consumption. Due to these advantages, the wafer connection through contact terminals is being investigated as an approach to fabricate devices for mobile phones. (c) of FIG. 1 illustrates a wafer-level packaging technique in which sensors s are mounted on the surface of a wafer w, barriers g are disposed to surround the sensors, and accessories, such as upper lenses, are directly attached thereto. This technique also makes the fabrication of devices simpler, contributing to a reduction in fabrication cost Due to this advantage, many attempts have been made to develop an improved wafer-level packaging technique.

Various semiconductor processes, such as photolithography, etching, deposition, flux application, and ball attach, are required to produce three-dimensional wafer surfaces. During the above-described processes, various kinds of residues axe left on the final three-dimensional wafer surfaces.

Residues are removed from the surface of a three-dimensional wafer by a series of sequential wet, cleaning, rinsing, and drying processes. The wet cleaning, process is carried out. by spraying a chemical solution, such as an acid-alkali solvent Or an organic solvent, on the surface of the wafer, the rinsing process is carried out by removing solution residues using ultrapure water, and the drying process is carried out by drying the wafer while spinning the wafer at thousands of rpm. However, after completion of the processes, particulate residues r are left around three-dimensional structures (for example, contact pads, contact bumps, sensors or barriers) formed on the surface of the water, as illustrated in FIG. 2. In addition to the residues, water marks in are observed around the three-dimensional structures when the drying is incomplete. Particularly, when the wafer is dried while spinning, considerable amounts of contaminants remain unremoved in the central portion of the wafer on which a sufficient centrifugal force does not act. Residues remaining around contact terminals even after cleaning cause serious problems, such as short-circuiting and current leakage, after subsequent terminal bonding between the wafer and an adjacent wafer or between the wafer and a PCB, which adversely affect the production yield.

### PRIOR ART DOCUMENTS

### Patent Documents

Korean Patent Publication No. 10-2014-0077087 (published on Jun. 23, 2014)

### DETAILED DESCRIPTION OF THE INVENTION

### Technical Tasks

The present invention has been made to solve the problems of the prior art, and it is an object of the present invention to provide a cleaning method and apparatus by which the surface of a three-dimensional wafer formed with three-dimensional surface structures, such as contact terminals (for example, contact pads or contact bumps), sensors, and/or barriers, is reliably cleaned with CO₂ dry ice accelerated with clean air so that residues present around the 3-dimensional structures can be completely removed.

### Technical Solutions

One aspect of the present invention provides an apparatus for removing residues present on the surface of a three-dimensional wafer formed with three-dimensional surface structures to clean the surface of the three-dimensional wafer. Specifically, the apparatus includes a wafer support for supporting a three-dimensional wafer and a CO₂ dry ice spray unit for producing solid CO₂ dry ice through adiabatic expansion of liquid CO₂ at or near a cleaning nozzle and spraying the solid CO₂ dry ice on the surface of the three-dimensional wafer through the cleaning nozzle wherein the CO₂ dry ice spray unit includes a liquid CO₂ feeder for supplying the liquid CO₂ to the cleaning nozzle and an accelerated clean air feeder for supplying clean air to the cleaning nozzle.

According to one embodiment, the wafer support spins the three-dimensional water in a fixed state.

According to one embodiment, the apparatus of the present invention further includes a swinging/turning drive unit for swinging the cleaning nozzle across the three-dimensional wafer to clean the entire area of the wafer.

According to one embodiment, the apparatus of the present invention further includes a blowing air spray unit for blowing out residues, which are separated from the surface of the three-dimensional wafer by collision with the solid CO₂ dry ice, from the surface of the three-dimensional wafer to prevent the residues from being reattached to the three-dimensional wafer wherein the blowing air spray unit includes a blowing air spray nozzle positioned close to the cleaning nozzle and a blowing air feeder for supplying clean air to the blowing air spray nozzle through a blowing air supply line.

According to one embodiment, the apparatus of the present invention further includes an ionized air spray unit for spraying ionized air to clear static electricity generated in a cleaning area by the solid CO₂ dry ice wherein the ionized air spray unit includes an ionized air spray nozzle and an ionized air feeder for supplying ionized air to the ionized air spray nozzle through an ionized air supply line.

According to one embodiment, the apparatus of the present invention further includes a dust collecting unit for removing the residues separated from the surface of the three-dimensional wafer by suction.

According to one embodiment, the apparatus of the present invention further includes an air guide structure defining a concavely shaped space around the three-dimensional wafer supported on the water support to downwardly guide a flow of air wherein an air suction part is positioned under the air guide structure to suck the air and vent the air to the outside.

According to one embodiment, the solid CO₂ dry ice has a particle size of 500 μm or less and the clean air is preferably sprayed at a pressure of S bar or less to accelerate the solid CO₂ dry ice.

A further aspect of the present invention provides a method for removing residues present on the surface of a three-dimensional wafer formed with three-dimensional surface structures to clean the surface of the three-dimensional wafer, the method including: spinning a three-dimensional wafer supported on a water support; adiabatically expanding liquid CO₂ to produce solid CO₂ dry ice and spraying the solid CO₂ dry ice on the surface of the three-dimensional wafer through a cleaning nozzle; and blowing out residues, which are separated from the surface of the three-dimensional wafer by collision with the solid CO₂ dry ice, with clean air sprayed through a blowing air spray nozzle.

Another aspect of the present invention provides a method for removing residues present on the surface of a three-dimensional wafer formed with three-dimensional surface structures to clean the surface of the three-dimensional wafer, the method including: spinning a three-dimensional wafer supported on a wafer support; adiabatically expanding liquid CO₂ to produce solid CO₂ dry ice and spraying the solid CO₂ dry ice on the surface of the three-dimensional wafer through a cleaning nozzle; and clearing static electricity, which is generated by collision with the solid CO₂ dry ice, with ionized air sprayed through an ionized air spray nozzle.

Still another aspect of the present invention provides a method for removing residues present on the surface of a three-dimensional wafer formed with three-dimensional surface structures to clean the surface of the three-dimensional wafer, the method including: spinning a three-dimensional wafer supported on a wafer support; adiabatically expanding liquid CO₂ to produce solid CO₂ dry ice and spraying the solid CO₂ dry ice on the surface of the three-dimensional wafer through a cleaning nozzle; and swinging the cleaning nozzle, through which the solid CO₂ dry ice is sprayed, to clean the entire area of the three-dimensional wafer.

### Advantageous Effects

The three-dimensional wafer cleaning techniques of the present invention are effective in completely removing residues formed around three-dimensional structures on the surface of a wafer compared to conventional chemical wet cleaning techniques and can fundamentally prevent the formation of new residues, such as water marks, around the three-dimensional structures. Therefore, the present invention contributes to a remarkable yield improvement in the fabrication of multilayer semiconductor devices through processes for bonding wafers or bonding wafers to PCBs. In addition, the three-dimensional wafer cleaning techniques of the present invention are based on dry cleaning. Due to this feature, the present invention does not require the use of chemicals, such as acid-alkali organic solvents, avoiding the need for post-processing operations and dangerous working environments. Furthermore, the present invention does not require rinsing and drying processes, enabling very fast wafer cleaning.

### BRIEF DESCRIPTION OF THE DRAWINGS

(a), (b), and (c) of FIG. 1 illustrate the shapes of representative three-dimensional wafers.

FIG. 2 illustrates the shapes of residues formed on the surface of a three dimensional wafer after wet cleaning with a chemical solution.

FIG. 3 illustrates the construction of a three-dimensional wafer surface cleaning apparatus according to the present invention.

FIG. 4 is a view for explaining a method for cleaning the surface of a three-dimensional wafer while swinging a cleaning nozzle of the apparatus illustrated in FIG. 3.

FIG. 5 is a view for explaining a further embodiment of the present invention.

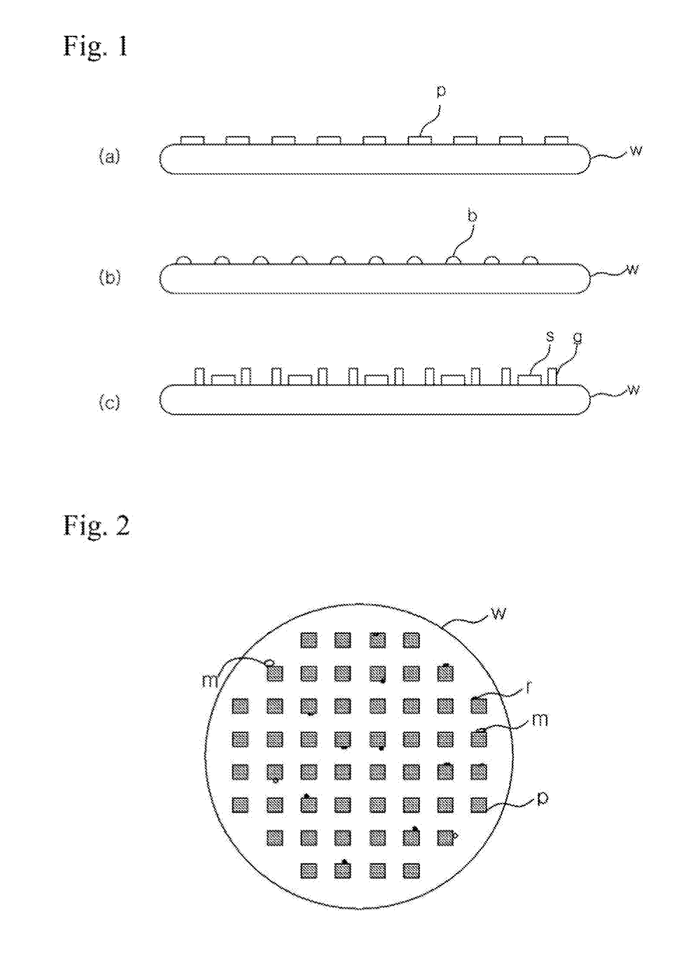

### BEST MODE FOR CARRYING OUT THE INVENTION

Preferred embodiments of the present invention will now be described in detail with reference to the accompanying drawings.

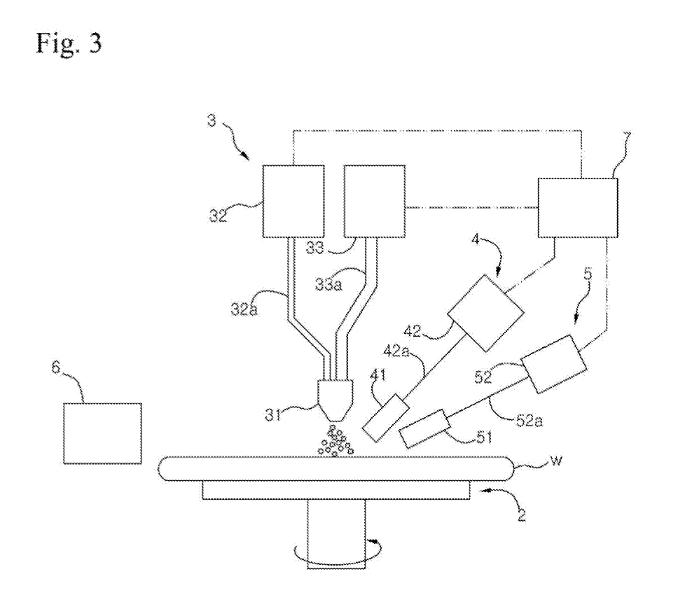

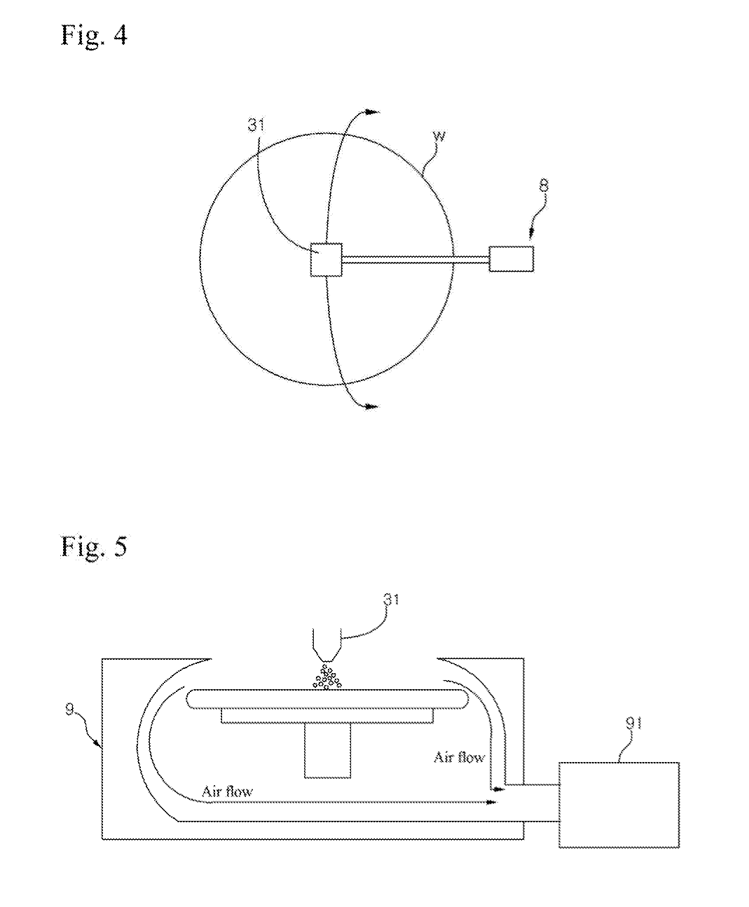

FIG. 3 illustrates the construction of a three-dimensional wafer surface cleaning apparatus according to the present invention, FIG. 4 is a view for explaining a method for cleaning the surface of a three-dimensional wafer while swinging a cleaning nozzle of the apparatus illustrated in FIG. 3, and FIG. 5 is a view for explaining the construction of the apparatus illustrated in FIG. 3 to prevent the surface of a three-dimensional wafer from being re-contaminated by air returning during cleaning of the wafer.

As illustrated in FIG. 3, the apparatus 1 is constructed such that the surface of a three-dimensional wafer w formed with three-dimensional surface structures, such as contact terminals (for example, bumps or pads), sensors, and barriers, is dry cleaned with CO₂ dry ice. For this dry cleaning, the apparatus includes a wafer support 2 for supporting a three-dimensional wafer wand a CO₂ dry ice spray unit 3 for spraying solid CO₂ dry ice on the surface of the three-dimensional wafer w supported on the wafer support 2.

The apparatus 1 further includes a blowing air spray unit 4 for blowing out residues, which are separated from the surface of the three-dimensional wafer w by collision with the solid CO₂ dry ice thereinafter referred to simply as “separated residues”), from the surface of the wafer w to prevent the residues from being reattached to the wafer w, an ionized air spray unit 5 for spraying ionized air on a cleaning area of the surface of the wafer w to clear static electricity generated by friction upon collision between the CO₂ dry ice and the surface of the wafer w, and a dust collecting unit 6 for removing dust or the separated residues formed during dry cleaning with the solid CO₂ dry ice by suction.

The apparatus 1 further includes an integrated control unit 7 for integrally controlling the above-described units, particularly the CO₂ dry ice spray unit 3, the blowing air spray unit 4, and the ionized air spray unit 5.

The wafer support 2 supports the wafer w to allow one side of the three-dimensional wafer w to be exposed upwardly and includes a chuck for fixing the three-dimensional wafer w and a rotary drive device including a motor adapted to spin the three-dimensional wafer w fixed to the chuck. As the chuck, a vacuum chuck or an electrostatic chuck may be used.

The CO₂ dry ice spray unit 3 includes a cleaning nozzle 31 directed toward the wafer w supported on the wafer support 2, a liquid CO₂ feeder 32 for supplying liquid CO₂ to the cleaning nozzle 31 through a liquid CO₂ supply line 32a, and an accelerated clean air feeder 33 for supplying clean air to the cleaning nozzle 31 through an accelerated clean air supply line 33a. The liquid CO₂ supplied from the liquid CO₂ feeder 32 is supplied to the cleaning nozzle 31 through the liquid CO₂ supply line 32a. The liquid CO₂ undergoes adiabatic expansion due to a momentary pressure drop in the connection portion between the liquid CO₂ supply line 32a and the cleaning nozzle 31, and as a result, it is convened to solid CO₂ dry ice. The resulting solid CO₂ dry ice is accelerated by clean air introduced and supplied from the accelerated clean air feeder 33 through the accelerated clean air supply line 33a. The accelerated solid CO₂ dry ice is sprayed on the surface of the wafer w through the outlet of the cleaning nozzle 31.

The sprayed solid CO₂ dry ice particles collide with residues present on the surface of the wafer w and the resulting collision energy causes the separation of the residues from the surface of the wafer w. If the size of the sprayed solid CO₂ dry ice particles is above a predetermined level, damage to the surface of the wafer w may be caused. It is thus preferred that the CO₂ dry ice spray unit 3 is designed to spray the solid CO₂ dry ice particles having a diameter of 500 μm or less. If the solid CO₂ dry ice is sprayed at too high a rate, the collision momentum becomes large, causing damage to $ the surface of the wafer w. It is thus preferred to adjust the pressure of the air sprayed from the cleaning nozzle 31 to 5 bar or less.

For effective wafer cleaning, the CO₂ dry ice spray unit 3 is also designed such that the solid CO₂ dry ice is sprayed through the cleaning nozzle 31 while swinging the cleaning nozzle 31. This design will be described in more detail below.

The additional blowing air spray unit 4 serves to prevent residues separated from the wafer w by spray cleaning from being reattached to the surface of the wafer w, as mentioned above. The blowing air spray unit 4 includes a blowing air spray nozzle 42 positioned close to the cleaning nozzle 31 of the CO₂ dry ice spray unit 3 and a blowing air feeder 42 for supplying clean air to the blowing air spray nozzle 41. During spray cleaning with the solid CO₂ dry ice, the blowing air spray unit 4 sprays clean air at a pressure above a predetermined level on or near a cleaning area of the wafer w, enabling effective permanent removal of the residues.

The ionized air spray unit 5 serves to clear static electricity that may be generated by friction upon collision between the CO₂ dry ice and the surface of the wafer w, as mentioned above. Static electricity generated on the surface of the wafer w increases the risk of failure of sensitive semiconductor devices. There is thus a need to immediately clear static electricity that may be generated during cleaning. To this end, the ionized air spray unit 5 includes an ionized air spray nozzle 51 through which electrically ionized air is sprayed and an ionized air feeder 52 for supplying the ionized air to the ionized air spray nozzle 51 through an ionized air supply line 52a.

The integrated control unit 7 functions to individually control the liquid CO₂ feeder 32, the accelerated clean air feeder 33, the blowing air feeder 42, and the ionized air feeder 52. Specifically, the integrated control unit 7 can individually control the amount (force) of CO₂ dry ice sprayed from the spray unit 3, the amount (force) of blowing air sprayed from the blowing air spray unit 4, the amount (force) of ionized air sprayed from the ionized air spray unit 5, and ON/OFF of the spray units 3, 4, and 5.

Referring to FIG. 4. visible is as winging/turning drive unit 8 for swinging the cleaning nozzle 31 to improve the cleaning effect by CO₂ dry ice spray. The swinging/turning drive unit 8 is designed to swing the cleaning nozzle 31 of the CO₂ dry ice spray unit from side to side across the three-dimensional wafer w in the diametral direction. Due to this design, the entire area of the spinning three-dimensional wafer w is cleaned. The left and right swinging range of the cleaning nozzle 41 is determined to be broader than the range between the opposite lateral edges of the wafer w. Therefore, the combination of the swinging of the cleaning nozzle and the spinning of the wafer w enables cleaning of the entire area of the wafer w. The swinging/turning drive unit 8 has the function of adjusting the height of the cleaning nozzle 31. With this function, the cleaning operation can be performed while facilitating the adjustment of the cleaning power and range of the cleaning nozzle 31. Although FIG. 4 illustrates a. state in which the cleaning nozzle 31 is connected only to the swinging/turning drive unit 8, the blowing air spray nozzle 41 and or the ionized air spraying nozzle 51 may be also connected to the swinging/turning drive unit 8.

A brief explanation will be given of a method for cleaning the surface of a three-dimensional wafer w using the apparatus 1 illustrated, in FIGS. 3 and 4.

First, the three-dimensional wafer w is fixed to the wafer support 2. A vacuum chuck or an electrostatic chuck may be used to fix the three-dimensional wafer w. Next, the support 2 rotates to spin the three-dimensional wafer w. Then, the CO₂ dry ice spray unit 3 sprays solid CO₂ dry ice on the surface of the three-dimensional wafer w through the cleaning nozzle 31 under the control of the integrated control unit 7 to separate residues from the surface of the wafer w. In this process, the blowing air spray unit 4 sprays clean air through the blowing air spray nozzle 41 to blow out the residues separated from the surface of the wafer w under the control of the integrated control unit 7. Likewise, the ionized air spray unit 5 sprays ionized air through the ionized air spray nozzle 51 under the control of the control unit 7 to clear possible static electricity generated on the surface of the wafer w. In addition to these supply units 3, 4, and 5, the dust collecting unit 6 is provided to remove the separated residues or dust by suction. The entire area of the wafer w can be cleaned by the left and right swinging of the cleaning nozzle 31 simultaneously with the spinning of the three-dimensional wafer w. The cleaning power of the cleaning nozzle 31 can also be controlled by adjusting the height of the cleaning nozzle 31. The functions of the units of the cleaning apparatus together with the operations of the units in the corresponding steps of the cleaning method have already been explained and thus unexplained details in this paragraph follow the foregoing description regarding the apparatus.

FIG. 5 is a view for explaining a further embodiment of the present invention. Referring to FIG. 5, the apparatus 1 further includes an air guide structure 9 installed to downwardly guide air present around the wafer w while surrounding the periphery of the support 2 supporting the wafer w.

The residues separated by the solid CO₂ dry ice sprayed from the cleaning nozzle 31 move along a flow of the air. Therefore, it is very important to determine the shapes of structures surrounding the wafer w and the direction of the air flow. As illustrated in FIG. 5, the air guide structure 9 defines a concavely shaped space around the wafer w to downwardly guide the flow of the air. An air suction part 91 is positioned under the air guide structure 9 to collect all air flows and suck the air in one direction. The air suction part 91 can prevent the wafer from being re-contaminated by the returning air. The air suction part 91 may be a ventilation fan positioned under the air guide structure 9 to vent the air to the outside.

The preferred embodiments of the present invention are merely illustrative and those skilled in the art will recognize that modifications and variations can be made without departing from the spirit and scope of the invention as defined by the appended claims.

1. An apparatus for removing residues present on the surface of a three-dimensional wafer formed with three-dimensional surface structures to dean the surface of the three-dimensional wafer, the apparatus comprising a v support for supporting the three-dimensional wafer and a CO₂ dry ice spray unit for producing solid CO₂ dry ice through adiabatic expansion of liquid CO₂ at or near a cleaning nozzle and spraying the slid CO₂ dry ice on the surface of the three-dimensional water through the cleaning nozzle wherein the CO₂ dry ice spray unit comprises a liquid CO₂feeder for supplying the liquid CO₂ to the cleaning nozzle and an accelerated clean air feeder for supplying clean air to the cleaning nozzle.

2. The apparatus according to claim 1, wherein the wafer support spins the three-dimensional wafer in a fixed state.

3. The apparatus according to claim 2, further comprising a swinging/turning drive unit for swinging the cleaning nozzle across the three-dimensional wafer to dean the entire area of the wafer.

4. The apparatus according to claim 1, further comprising a blowing air spray unit for blowing out residues, which are separated from the surface of the three-dimensional wafer by collision with the solid CO₂ dry ice, from the surface of the three-dimensional wafer to prevent the residues from being reattached to the three-dimensional wafer.

5. The apparatus according to claim 4, wherein the blowing air spray unit comprises a blowing air spray nozzle positioned close to the cleaning nozzle and a blowing air feeder for supplying clean air to the blowing air spray nozzle through a blowing air supply line.

6. The apparatus according to claim 1, further comprising an ionized air spray unit for spraying ionized air to clear static electricity generated in a cleaning area by the solid CO₂ dry ice.

7. The apparatus according to claim 6, wherein the ionized air spray unit comprises an ionized air spray nozzle and an ionized air feeder for supplying ionized air to the ionized air spray nozzle through an ionized air supply line.

8. The apparatus according to claim 1, further comprising a dust collecting unit for removing the residues separated from the surface of the three-dimensional wafer by suction.

9. The apparatus according to claim 1, further comprising an air guide structure defining a concavely shaped space around the three-dimensional wafer supported on the wafer support.

10. The apparatus according to claim 9 wherein the air guide structure downwardly guides a flow of air around the three-dimensional wafer and an air suction part is positioned under the air guide structure to suck the air and vent the air to the outside.

11. The apparatus according to claim 1, wherein the solid CO₂ dry ice has a particle size of 500 μm or less.

12. The apparatus according to claim 11, wherein the clean air is sprayed at a pressure of 5 bar or less to accelerate the solid CO₂ dry ice.

13. A method for removing residues present on the surface of a three-dimensional wafer formed with three-dimensional surface structures to clean the surface of the three-dimensional wafer, the method comprising: spinning a three-dimensional wafer supported on a wafer support; adiabatically expanding liquid CO₂ to produce solid CO₂ dry ice and spraying the solid CO₂ dry ice on the surface of the three-dimensional wafer through a cleaning nozzle; and blowing out residues, which are separated from the surface of the three-dimensional wafer by collision with the solid CO₂ dry ice, with clean air sprayed through a blowing air spray nozzle.

14. A method for removing residues present on the surface of a three-dimensional wafer formed with three-dimensional surface structures to clean the surface of the three-dimensional wafer, the method comprising: spinning a three-dimensional wafer supported on a water support; adiabatically expanding liquid CO₂ to produce solid CO₂ dry ice and spraying the solid CO₂ dry ice on the surface of the three-dimensional wafer through a cleaning nozzle; and clearing static electricity, which is generated by collision with the solid CO₂ dry ice, with ionized air sprayed through an ionized air spray nozzle.

15. A method for removing residues present on the surface of a three-dimensional water formed with three-dimensional surface structures to clean the surface of the three-dimensional wafer, the method comprising: spinning a three-dimensional wafer supported on a wafer support adiabatically expanding liquid CO₂ to produce solid CO₂ dry ice and spraying the solid CO₂ dry ice on the surface of the three-dimensional wafer through a cleaning nozzle; and swinging the cleaning nozzle, through which the solid CO₂ dry ice is sprayed, to clean the entire area of the three-dimensional water.
